(19) United States
(12) Patent Application Publication
(10) Pub. No.: US 2025/0126715 A1
(43) Pub. Date: Apr. 17, 2025

(54) PRINTED CIRCUIT BOARD

(71) Applicant: SAMSUNG ELECTRO-MECHANICS CO., LTD., Suwon-si (KR)

(72) Inventors: Byung Hak KANG, Suwon-si (KR); Seung Eun LEE, Suwon-si (KR)

(73) Assignee: SAMSUNG ELECTRO-MECHANICS CO., LTD., Suwon-si (KR)

(21) Appl. No.: 18/672,524

(22) Filed: May 23, 2024

(30) Foreign Application Priority Data
Oct. 13, 2023 (KR) 10-2023-0136403
Nov. 15, 2023 (KR) 10-2023-0157812

(51) Int. Cl. H05K 1/14; H05K 1/11; H05K 3/30; H05K 3/38

(52) U.S. Cl. CPC H05K 1/144; H05K 1/115; H05K 3/303; H05K 3/38; H05K 2201/0175; H05K 2201/0179; H05K 2201/032; H05K 2201/0341; H05K 2201/041; H05K 2201/096; H05K 2201/09827; H05K 2203/0278; H05K 2203/1105

(57) ABSTRACT

A printed circuit board includes a first substrate including a first wiring layer; a second substrate disposed on the first substrate and including a second wiring layer; a metal layer disposed between the first and second substrates; and a bonding layer disposed between the first and second substrates. Each of the first and second substrates includes an organic material, and the bonding layer includes an inorganic material.

### CROSS-REFERENCE TO RELATED APPLICATIONS

This application claims benefit of priority to Korean Patent Application No. 10-2023-0157812 filed on Nov. 15, 2023 and Korean Patent Application No. 10-2023-0136403 filed on Oct. 13, 2023 in the Korean Intellectual Property Office, the disclosures of which are incorporated herein by reference in their entirety.

### TECHNICAL FIELD

The present disclosure relates to a printed circuit board, for example, a package substrate.

### BACKGROUND

Due to improved performance of a semiconductor chip, demand for a high-density package substrate has increased. Accordingly, it may be necessary to develop a package substrate which may reduce a bump pitch, may be multi-layered and have a large area, and may improve signal and power characteristics. In particular, the implementation of a fine circuit has been important to respond to the increasing number of input/output terminals. In the case in which a fine circuit of a substrate develops, a single chip package (SCP) and a single/multi-chip package (MCP) and also a 2.5D silicon interposer may be replaced.

### SUMMARY

An aspect of the present disclosure is to provide a multilayer printed circuit board including a fine circuit.

An aspect of the present disclosure is to provide a printed circuit board which may reduce manufacturing costs through high yield and a process efficiency.

An aspect of the present disclosure is to manufacture a multilayer printed circuit board by manufacturing a first substrate including a fine circuit and a second substrate, and bonding the first and second substrates using hybrid metal bonding.

For example, according to an example embodiment, a printed circuit board includes a first substrate including a first wiring layer; a second substrate disposed on the first substrate and including a second wiring layer; a metal layer disposed between the first and second substrates; and a bonding layer disposed between the first and second substrates. Each of the first and second substrates includes an organic material, and the bonding layer includes an inorganic material.

For example, according to an example embodiment, a printed circuit board includes a first substrate including a first wiring layer; a second substrate disposed on the first substrate and including a second wiring layer; a metal layer disposed between the first and second substrates; and a bonding layer disposed between the first and second substrates. A wiring line having a minimum line width among wiring lines of the second wiring layer has a line width smaller than a line width of a wiring line having a minimum line width among wiring lines of the first wiring layer.

For example, according to an example embodiment, a method of manufacturing a printed circuit board includes preparing a first substrate including a plurality of first wiring layers and having a first metal layer formed on an outermost side; forming a first inorganic insulating film covering at least a portion of the first metal layer on the outermost side of the first substrate; preparing a second substrate including a plurality of second wiring layers and having a second metal layer formed on an outermost side; forming a second inorganic insulating film covering at least a portion of the second metal layer on the outermost side of the second substrate; and bonding the first and second substrates to each other such that the first and second inorganic insulating films are bonded to each other and the first and second metal layers are bonded to each other, wherein each of the first and second substrates includes an organic material.

For example, according to an example embodiment, a printed circuit board includes a first substrate including a plurality of first insulating layers, a plurality of first wiring layers disposed on or in the plurality of first insulating layers, and a plurality of first via layers penetrating at least one of the plurality of first insulating layers, respectively; a second substrate disposed on the first substrate and including a plurality of second insulating layers, a plurality of second wiring layers disposed on or in the plurality of second insulating layers, respectively, and a plurality of second via layers penetrating at least one of the plurality of second insulating layers, respectively; a metal layer disposed between the first and second substrates to connect a via layer among the plurality of first via layers which is closest to the second substrate and a via layer among the plurality of second via layers which is closed to the first substrate to each other; and an insulating bonding layer disposed between the first and second substrates to connect to the first and second substrates to each other. The via layer among the plurality of first via layers which is closest to the second substrate and the plurality of second via layers are tapered in opposite directions.

For example, according to an example embodiment, a printed circuit board includes a first substrate including a plurality of first insulating layers, a plurality of first wiring layers disposed on or in the plurality of first insulating layers, and a plurality of first via layers penetrating at least one of the plurality of first insulating layers, respectively; a second substrate disposed on the first substrate and including a plurality of second insulating layers, a plurality of second wiring layers disposed on or in the plurality of second insulating layers, respectively, and a plurality of second via layers penetrating at least one of the plurality of second insulating layers, respectively; a metal layer disposed between the first and second substrates to connect a via layer among the plurality of first via layers which is closest to the second substrate and a via layer among the plurality of second via layers which is closed to the first substrate to each other; and an insulating bonding layer disposed between the first and second substrates to connect to the first and second substrates to each other. An outmost via layer of the plurality of second via layers, connected to an outmost wiring layer of the plurality of second wiring layers, has a tapered shape such that a width thereof increases in a direction towards the metal layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating an example of an electronic device system;

FIG. 2 is a plan diagram illustrating an example of an electronic device;

FIG. 3 is a cross-sectional diagram illustrating an example of a printed circuit board;

FIG. 4 is a cross-sectional diagram illustrating a modified example of the printed circuit board in FIG. 3;

FIGS. 5A to 5D are enlarged cross-sectional diagrams illustrating various examples of hybrid metal bonding;

FIGS. 6A and 6B are enlarged cross-sectional diagrams illustrating various examples of a boundary surface in intermetallic bonding;

FIG. 7 is a diagram illustrating an example of a method of manufacturing a printed circuit board;

FIGS. 8A to 8C are cross-sectional diagrams illustrating processes of an example of a method of manufacturing a first substrate portion;

FIGS. 9A to 9C are cross-sectional diagrams illustrating processes of an example of a method of manufacturing a second substrate portion;

FIGS. 10A and 10B are cross-sectional diagrams illustrating an example of bonding first and second substrate portions;

FIG. 11 is cross-sectional diagrams illustrating hybrid metal bonding;

FIG. 12 is a graph indicating a temperature cycle of hybrid metal bonding according to an example embodiment;

FIG. 13 is cross-sectional diagrams illustrating another example of hybrid metal bonding;

FIG. 14 is cross-sectional diagrams illustrating another example of hybrid metal bonding;

FIG. 15 is a cross-sectional diagram illustrating another example of a printed circuit board;

FIG. 16 is a cross-sectional diagram illustrating a modified example of the printed circuit board in FIG. 15;

FIG. 17 is a cross-sectional diagram illustrating another example of a printed circuit board;

FIG. 18 is a cross-sectional diagram illustrating a modified example of the printed circuit board in FIG. 17;

FIG. 19 is a cross-sectional diagram illustrating another example of a printed circuit board; and

FIG. 20 is a cross-sectional diagram illustrating a modified example of the printed circuit board in FIG. 19.

### DETAILED DESCRIPTION

Hereinafter, embodiments of the present disclosure will be described as follows with reference to the attached drawings.

### Electronic Device

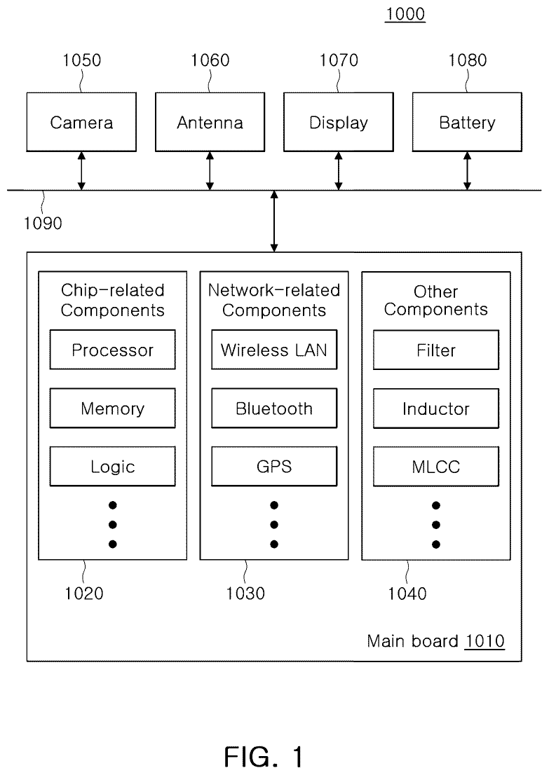

FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

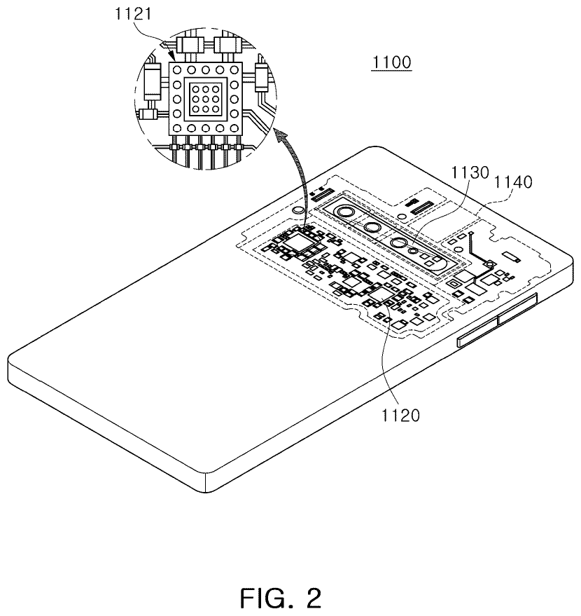

FIG. 2 is a plan diagram illustrating an example of an electronic device.

Referring to FIG. 2, an electronic device may be a smartphone 1100. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment example thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above.

### Printed Circuit Board

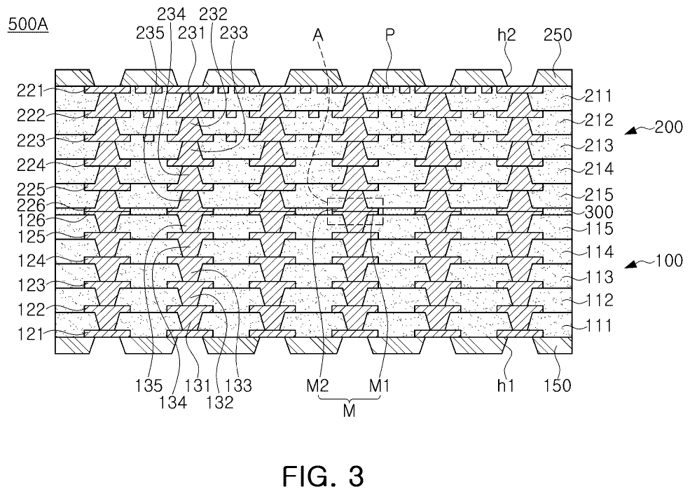

FIG. 3 is a cross-sectional diagram illustrating an example of a printed circuit board.

Referring to the drawing, a printed circuit board 500A according to an example may include a first substrate 100 including a plurality of first wiring layers 121, 122, 123, 124, 125, and 126 and including a first metal layer M1 disposed on an upper side thereon, a second substrate 200 disposed on the first substrate 100, and including a plurality of second wiring layers 221, 222, 223, 224, 225, and 226 and a second metal layer M2 disposed on a lower side thereon, and an insulating layer 300 disposed between the first and second substrates 100 and 200 and burying at least a portion of each of the first and second metal layers M1 and M2. If desired, a first resist layer 150 disposed on a lower side of the first substrate 100 and having a plurality of first openings h1 exposing at least a portion of a 1-1 wiring layer 121, and a second resist layer 250 disposed on the second substrate 200 and having a plurality of second openings h2 exposing at least a portion of a 2-1 wiring layer 221 may be further included. Each of the first and second substrates 100 and 200 may be configured as a multilayer substrate, as described later. The second substrate 200 may be configured as a fine circuit substrate having a relatively fine pitch as compared to the first substrate 100. For example, the second substrate 200 may be configured as a circuit substrate having higher-density than that of the first substrate 100. The first and second metal layers M1 and M2 may be bonded to each other using hybrid metal bonding along with the insulating layer 300. For example, an upper surface of the first metal layer M1 and a lower surface of the second metal layer M2 may be bonded to each other. The first and second metal layers M1 and M2 may be bonded to each other and may be integrated into the metal layer M. A boundary between the first and second metal layers M1 and M2 may or may not be distinct. The bonding layer 300 may be disposed adjacent to the metal layer M.

To implement a fine circuit, the substrate may use a semi additive process (SAP) or buried trace substrate (ETS) method. For example, by the ETS method, a structure in which a pattern may be buried in an insulating material, and no undercut may occur when etching a seed layer of chemical copper plating, such that adhesive force between a pattern and an insulating material may be excellent. Accordingly, regardless of excellence of the SAP or ETS method, low yield of a layer in which a fine circuit may be implemented may affect overall yield.

The printed circuit board 500A according to one example may have a structure in which the first substrate 100 having a relatively large wiring density, and the second substrate 200 having a relatively small wiring density may be separately manufactured and may be bonded using hybrid metal bonding. In this case, even when a low-density substrate is manufactured with a high yield and a high-density substrate is manufactured with a lower yield, only good quality substrates may be bonded to each other, thereby reducing a decrease in final cumulative yield. Also, using an optimized process according to density of wiring, a line width of a wiring line and a distance between the wiring lines, and a pitch of a wiring pad, process efficiency may be increased and efficiency may be obtained in terms of costs. Also, since the first and second substrates 100 and 200 may be bonded to each other through hybrid metal bonding by the insulating layer 300 and the first and second metal layers M1 and M2, an overall thickness of the substrate may be reduced, bonding reliability may be improved, and since it may be necessary to form a bonding pad, design freedom may be increased.

In the description below, the components of the printed circuit board 500A according to an example may be described in greater detail with reference to the drawings.

The first substrate 100 may be configured as a multilayer printed circuit board. For example, the first substrate 100 may include a plurality of first insulating layer 111, 112, 113, 114, and 115, a plurality of first wiring layers 121, 122, 123, 124, 125, and 126 disposed on or in the plurality of first insulating layer 111, 112, 113, 114, and 115, respectively, and a plurality of first via layers 131, 132, 133, 134, and 135 penetrating at least one of the plurality of first insulating layers 111, 112, 113, 114, and 115, respectively. Among the plurality of first wiring layers 121, 122, 123, 124, 125, and 126, a wiring layer 1-6 disposed on an uppermost side may include the first metal layer M1. The first substrate 100 may be configured as a coreless-type multilayer printed circuit board not including a core layer. At least one of the plurality of first insulating layers 111, 112, 113, 114, and 115 may include an organic material.

The plurality of first insulating layers 111, 112, 113, 114, and 115 may be configured as an organic insulating layer. For example, the plurality of first insulating layers 111, 112, 113, 114, and 115 may include an organic insulating material. The organic insulating material may include a thermosetting resin such as an epoxy resin, a thermoplastic resin such as polyimide, or a material including an inorganic filler, an organic filler, and/or glass fiber (glass cloth, glass fabric) along with resin. For example, the organic insulating material may be a non-photosensitive insulating material such as copper clad laminate (CCL), Ajinomoto build-up film (ABF), or prepreg (PPG), but an example embodiment example thereof is not limited thereto, and other polymer materials may be used. The glass core layer may include glass. If desired, at least one of the plurality of first insulating layers 111, 112, 113, 114, and 115 may include other types of insulating materials other than an organic insulating material such as glass and ceramic. However, even in this case, other layers may include an organic insulating material.

Each of the plurality of first wiring layers 121, 122, 123, 124, 125, and 126 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment example thereof is not limited thereto. Each of the plurality of first wiring layers 121, 122, 123, 124, 125, and 126 may perform various functions depending on a design. For example, a signal pattern, a power pattern, and a ground pattern may be included. The patterns may have various forms such as a line form, a plain form, and a pad form. Each of the plurality of first wiring layers 121, 122, 123, 124, 125, and 126 may include a seed layer and a plating layer formed on the seed layer. The seed layer may be an electroless plating layer (or chemical copper) and/or a sputtering layer, and the plating layer may be an electrolytic plating layer (or electrical copper), but an embodiment example thereof is not limited thereto. A 1-1 wiring layer 121 may be buried in a lower side of the 1-1 insulating layer 111, such that the lower surface may be exposed from a lower surface of the 1-1 insulating layer 111-1. The 1-2 wiring layer 122 may be disposed on an upper surface of the 1-1 insulating layer 111 and buried in the 1-2 insulating layer 112. The 1-3 wiring layer 123 may be disposed on an upper surface of the 1-2 insulating layer 112 and may be buried in the 1-3 insulating layer 113. The 1-4 wiring layer 124 may be disposed on an upper surface of the 1-3 insulating layer 113 and may be buried in the 1-4 insulating layer 114. The 1-5 wiring layer 125 may be disposed on an upper surface of the 1-4 insulating layer 114 and may be buried in the 1-5 insulating layer 115. The 1-6 wiring layer 126 may be disposed on an upper surface of the 1-5 insulating layer 115. However, an embodiment example thereof is not limited thereto.

The first metal layer M1 may include various types of conductor patterns. The first metal layer M1 may be disposed in a position substantially corresponding to the second metal layer M2, and the conductor pattern of the first metal layer M1 may have a shape substantially corresponding to a conductor pattern of the second metal layer M2. The 1-6 wiring layer 126 including the first metal layer M1 may be planarized as in a process described later, and may have a thickness smaller than those of the other 1-1, 1-2, 1-3, 1-4, and 1-5 wiring layers 121, 122, 123, 124, and 125.

Each of the plurality of first via layers 131, 132, 133, 134, and 135 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment example thereof is not limited thereto. Each of the plurality of first via layers 131, 132, 133, 134, and 135 may include a filled via filling a via hole, or may also include a conformal via disposed along a wall of the via hole. The plurality of first via layers 131, 132, 133, 134, and 135 may perform various functions depending on a design. For example, a ground via, a power via, and a signal via may be included. Each of the plurality of first via layers 131, 132, 133, 134, and 135 may include an electroless plating layer (or chemical copper) and an electrolytic plating layer (or electric copper). A sputtering layer may be included instead of an electroless plating layer (or chemical copper), and, if desired, both may be included. Each of the 1-1, 1-2, 1-3, 1-4, and 1-5 and the via layers 131, 132, 133, 134, and 135 may have a tapered shape in the same direction in a cross-section. For example, an upper end may be greater than a lower end in each cross-section.

The second substrate 200 may be configured as a multilayer printed circuit board. For example, the second substrate 200 may include a plurality of second insulating layers 211, 212, 213, 214, and 215, a plurality of second wiring layers 221, 222, 223, 224, 225, and 226 disposed on or in the plurality of second insulating layers 211, 212, 213, 214, and 215, respectively, and a plurality of second via layers 231, 232, 233, 234, and 235 penetrating at least one of the plurality of second insulating layers 211, 212, 213, 214, and 215, respectively. Among the plurality of second wiring layers 221, 222, 223, 224, 225, and 226, a 2-6 wiring layer 226 disposed on a lowermost side may include the second metal layer M2. The second substrate 200 may be configured as a coreless type multilayer printed circuit board not including a core layer. At least one of the plurality of second insulating layers 211, 212, 213, 214, and 215 may include an organic material.

The plurality of second insulating layers 211, 212, 213, 214, and 215 may be an organic insulating layer. For example, the plurality of second insulating layers 211, 212, 213, 214, and 215 may include an organic insulating material. The organic insulating material may include a thermosetting resin such as an epoxy resin, a thermoplastic resin such as polyimide, or a material including an inorganic filler, an organic filler, and/or glass fiber (glass cloth, glass fabric) along with resin. For example, the organic insulating material may be a non-photosensitive insulating material such as copper clad laminate (CCL), Ajinomoto build-up film (ABF), or prepreg (PPG), but an example embodiment example thereof is not limited thereto, and other polymer materials may be used. If desired, plurality of second insulating layers 211, 212, 213, 214, and 215 may each include a photosensitive insulating material such as a photoimageable dielectric (PID). If desired, the plurality of second insulating layers 211, 212, 213, 214, and 215 may include other types of insulating materials other than an organic insulating material such as glass and ceramic. However, even in this case, the other layers may include an organic insulating material.

The plurality of second insulating layers 211, 212, 213, 214, and 215 may have the same number of layers as the plurality of first insulating layers 111, 112, 113, 114, and 115, and an overall thickness may be substantially the same. Also, the plurality of second wiring layers 221, 222, 223, 224, 225, and 226 may have the same number of layers as the plurality of first wiring layers 121, 122, 123, 124, 125, and 126. Also, the plurality of second insulating layers 211, 212, 213, 214, and 215 may include substantially the same insulating material as that of the plurality of first insulating layers 111, 112, 113, 114, and 115. For example, the first and second substrates 100 and 200 may have an approximately symmetrical structure. However, but an embodiment example thereof is not limited thereto, and the plurality of second insulating layers 211, 212, 213, 214, and 215 may include an insulating material different from that of the plurality of first insulating layers 111, 112, 113, 114, and 115. For example, the plurality of first insulating layers 111, 112, 113, 114, and 115 may include non-photosensitive insulating materials such as ABF (Ajinomoto Build-up Film) and PPG (Prepreg), whereas each of the plurality of second insulating layers 211, 212, 213, 214, and 215 may include a photosensitive insulating material such as a photoimageable dielectric (PID). In this case, the plurality of 2-1, 2-2, 2-3, 2-4, and 2-5 insulating layers 211, 212, 213, 214, and 215 may have thicknesses of the plurality of 1-1, 1-2, 1-3, 1-4, and 1-5 insulating layers 111, 112, 113, 114, and 115, respectively, but an embodiment example thereof is not limited thereto. Also, in this case, the plurality of 2-1, 2-2, 2-3, 2-4, and 2-5, 2-6 wiring layers 221, 222, 223, 224, 225, and 226 may have thicknesses of the plurality of 1-1, 1-2, 1-3, 1-4, and 1-5, 1-6 wiring layer 121, 122, 123, 124, 125, and 126, respectively, but an embodiment example thereof is not limited thereto.

The plurality of second wiring layers 221, 222, 223, 224, 225, and 226 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment example thereof is not limited thereto. Each of the plurality of second wiring layers 221, 222, 223, 224, 225, and 226 may perform various functions depending on a design. For example, a signal pattern, a power pattern, and a ground pattern may be included. Each of the patterns may have various forms such as a line form, a plain form, and a pad form. Each of the plurality of second wiring layers 221, 222, 223, 224, 225, and 226 may include a seed layer and a plating layer formed on the seed layer. The seed layer may be an electroless plating layer (or chemical copper) and/or a sputtering layer, and the plating layer may be an electrolytic plating layer (or electrical copper), but an embodiment example thereof is not limited thereto. The 2-1 wiring layer 221 may be buried in an upper side of the 2-1 insulating layer 211, such that an upper surface may be exposed from an upper surface of the 2-1 insulating layer 211-1. The 2-2 wiring layer 222 may be disposed on a lower surface of the 2-1 insulating layer 211 and may be buried in the 2-2 insulating layer 212. The 2-3 wiring layer 223 may be disposed on a lower surface of the 2-2 insulating layer 212 and may be buried in the 2-3 insulating layer 213. The 2-4 wiring layer 224 may be disposed on a lower surface of the 2-3 insulating layer 213 and may be buried in the 2-4 insulating layer 214. The 2-5 wiring layer 225 may be disposed on a lower surface of the 2-4 insulating layer 214 and may be buried in the 2-5 insulating layer 215. The 2-6 wiring layer 226 may be disposed on a lower surface of the 2-5 insulating layer 215. However, an embodiment example thereof is not limited thereto.

At least one of the plurality of second wiring layers 221, 222, 223, 224, 225, and 226, for example, the 2-1, 2-2, and 2-3 wiring layers 221, 222, and 223, may include a fine circuit pattern P. The fine circuit pattern P may have a line/space (L/S) of 10 μm/10 μm or less, for example, 2 μm/2 μm or less. For example, the 2-1, 2-2, 2-3 wiring layers 221, 222, and 223 may have a minimum line width of a wiring line, a minimum distance between wiring lines, and a minimum pitch of a wiring pad smaller than those of at least one of plurality of first wiring layers 121, 122, 123, 124, 125, and 126, preferably, the plurality of first wiring layers 121, 122, 123, 124, 125, and 126, respectively, and density of the wiring thereof may be higher. For example, the 2-1, 2-2, 2-3 wiring layers 221, 222, and 223 may have a line/space (L/S) of a line pattern for signal connection smaller than that of at least one of the plurality of first wiring layers 121, 122, 123, 124, 125, and 126, preferably, the plurality of first wiring layers 121, 122, 123, 124, 125, and 126, respectively.

The second metal layer M2 may include various types of conductor patterns. The second metal layer M2 may be disposed in a position substantially corresponding to the first metal layer M1, and a conductor pattern of the second metal layer M2 may have a shape substantially corresponding to a conductor pattern of the first metal layer M1. The 2-6 wiring layer 226 including the second metal layer M2 may be planarized as in a process described later, and accordingly, may be thinner than the other 2-1, 2-2, 2-3, 2-4, and 2-5 wiring layers 221, 222, 223, 224, and 225, respectively.

Each of the plurality of second via layers 231, 232, 233, 234, and 235 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment example thereof is not limited thereto. Each of the plurality of second via layers 231, 232, 233, 234, and 235 may include a filled via filling the via hole, or may also include a conformal via disposed along a wall surface of the via hole. The plurality of second via layers 231, 232, 233, 234, and 235 may perform various functions depending on a design. For example, a ground via, a power via, and a signal via may be included. Each of the plurality of second via layers 231, 232, 233, 234, and 235 may include an electroless plating layer (or chemical copper) and an electrolytic plating layer (or electric copper). A sputtering layer may be included instead of an electroless plating layer (or chemical copper), and, if desired, both may be included. Each of the 2-1, 2-2, 2-3, 2-4, and 2-5 via layers 231, 232, 233, 234, and 235 may have a tapered shape in the same direction in a cross-section. For example, a lower end may be greater than an upper end in each cross-section. For example, the 1-1, 1-2, 1-3, 1-4, and 1-5 via layers 131, 132, 133, 134, and 135 and the 2-1, 2-2, 2-3, 2-4, and 2-5 via layers 231, 232, 233, 234, and 235 may be tapered in opposite directions on a cross-section, respectively.

Among the plurality of first via layers 131, 132, 133, 134, and 135, the 1-5 via layer 135 disposed on an uppermost side may include a first connection via connected to the first metal layer M1, and among the plurality of second via layer 231, 232, 233, 234, and 235, the 2-5 via layer 235 disposed on a lowermost side may include a second connection via connected to the second metal layer M2, wherein the first and second connection vias may be tapered in opposite directions. For example, a width of an upper end of a first connection via may be greater than a width of a lower end in a cross-section. A width of a lower end of the second connection via may be greater than a width of an upper end in the cross-section.

The insulating layer 300 may include an insulating material which may be used for hybrid metal bonding. For example, the insulating layer 300 may include an inorganic insulating material. The inorganic insulating material may include, for example, at least one of SiO₂, SiN and SiCN, but an embodiment example thereof is not limited thereto. The insulating layer 300 may bury at least a portion of each of the first and second metal layers M1 and M2. For example, the insulating layer 300 may cover at least a portion of a side surface of each of the first and second metal layers M1 and M2. However, the insulating layer 300 may be spaced apart from a lower surface of the first metal layer M1 and an upper surface of the second metal layer M2. A thickness of the bonding layer 300 may be substantially the same as a thickness of the metal layer M.

The first and second resist layers 150 and 250 may include a liquid or film-type solder resist, but an embodiment example thereof is not limited thereto, and may include other organic insulating materials such as ABF. The first and second resist layers 150 and 250 may have first and second openings h1 and h2, respectively. A plurality of the first and second openings h1 and h2 may be provided. The first and second openings h1 and h2 may be formed as solder mask defined (SMD) and/or non-solder mask defined (NSMD). The first and second openings h1 and h2 may expose at least a portion of the 1-1 and 2-1 wiring layers 121 and 221, respectively, and a surface treatment layer may be disposed on an exposed surface of the pattern. The surface treatment layer may be formed by electrolytic gold plating, electroless gold plating, organic solderability preservative (OSP) or electroless tin plating, electroless silver plating, electroless nickel plating/substituted gold plating, direct immersion gold (DIG) plating, and hot air solder leveling (HASL), but an embodiment example thereof is not limited thereto.

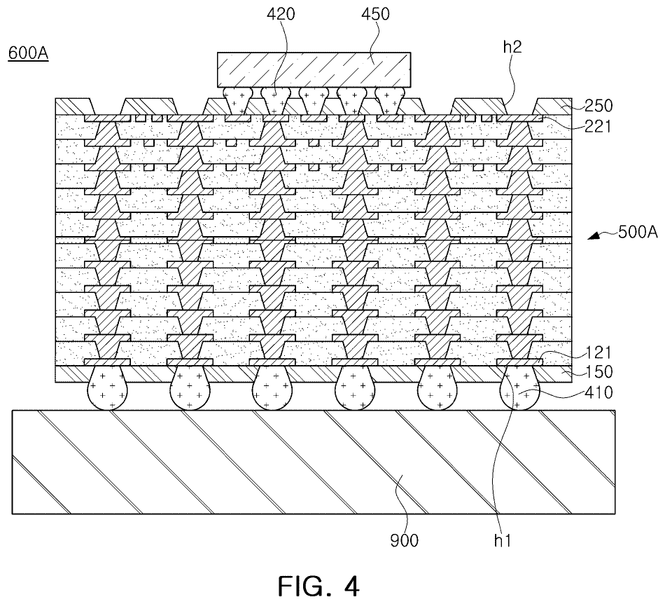

FIG. 4 is a cross-sectional diagram illustrating a modified example of the printed circuit board in FIG. 3.

Referring to the drawing, differently from the printed circuit board 500A, the printed circuit board 600A according to the modified example may further include a plurality of first connection metals 410 disposed on a plurality of first openings h1 of a first resist layer 150 and connected to at least portions of the 1-1 wiring layers 121, respectively, a plurality of second connection metals 420 disposed on at least portions of the plurality of second openings h2 of the second resist layer 250, respectively, and connected to at least portions of the 2-1 wiring layers 221, and a semiconductor chip 450 surface mounted on the second resist layer 250 through the plurality of second connection metals 420. For example, the printed circuit board 500A according to one example may have a package substrate structure, and the printed circuit board 600A according to a modified example may have a semiconductor package structure including the same. The printed circuit board 600A according to the modified example may be connected to and/or mounted on another substrate 900, such as a motherboard, through the plurality of second connection metals 420.

Each of the first and second connection metals 410 and 420 may be formed using a low melting point metal, for example, solder such as tin (Sn)-aluminum (Al)-copper (Cu), but an example embodiment thereof is not limited thereto, and the material thereof is not particularly limited thereto. The first and second connection metals 410 and 420 may be balls, pins, or the like. The first and second connection metals 410 and 420 may be formed as multiple layers or a single layer. When formed as multiple layers, a copper pillar and solder may be included, and when formed as a single layer, tin-silver solder may be included, but an example embodiment example thereof is not limited thereto. A plurality of the first and second connection metals 410 and 420 may be provided, and the number of the first and second connection metals 410 and 420 is not limited to any particular example.

The semiconductor chip 450 may include an integrated circuit (IC) die in which hundreds to millions of elements are integrated into a chip. In this case, the integrated circuit may be configured as, for example, a logic chip such as a central processor (e.g., CPU), graphics processor (e.g., GPU), field programmable gate array (FPGA), digital signal processor, cryptographic processor, microprocessor, microcontroller, application processor, (e.g., AP), an analog-to-digital converter, or an application-specific IC (ASIC), but an example embodiment thereof is not limited thereto, and the integrated circuit may be configured as a memory chip such as volatile memory (e.g. DRAM), non-volatile memory (e.g. ROM), flash memory, High Bandwidth Memory (HBM), or other types such as power management IC (PMIC). The semiconductor chip 160 may be formed based on an active wafer, and in this case, silicon (Si), germanium (Ge), gallium arsenide (GaAs), or the like, may be used as a base material for each body. Various circuits may be formed in the body. A connection pad may be formed on the body, and the connection pad may include a conductive material such as aluminum (Al) or copper (Cu). The semiconductor chip 450 may be configured as a bare die, and in this case, a metal bump may be disposed on the connection pad. The semiconductor chip 450 may be configured as a packaged die, and in this case, an additional redistribution layer may be formed on the connection pad, and a metal bump may be disposed on the redistribution layer. A plurality of semiconductor chips 450 may be provided, and in this case, the semiconductor chips 450 may be of the same or different type.

If desired, an electronic component (not illustrated) may be further surface-mounted on the second resist layer 250 through the plurality of second connection metals 420. The electronic component (not illustrated) may be a chip-type component, such as a high frequency inductor, a ferrite inductor, a power inductor, ferrite beads, a low temperature co-fired ceramic (LTCC), an electromagnetic interference (EMI) filter, a multilayer ceramic capacitor (MLCC), or the like, but an embodiment example thereof is not limited thereto. A plurality of electronic components (not illustrated) may be provided, and in this case, the electronic components (not illustrated) may be of the same or different type.

The other descriptions may be substantially the same as the descriptions described in the printed circuit board 500A according to the aforementioned example. Accordingly, overlapping descriptions will not be provided.

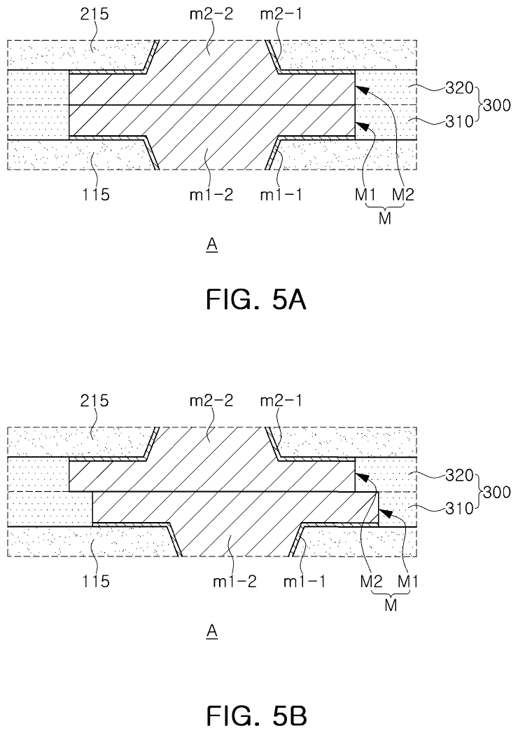

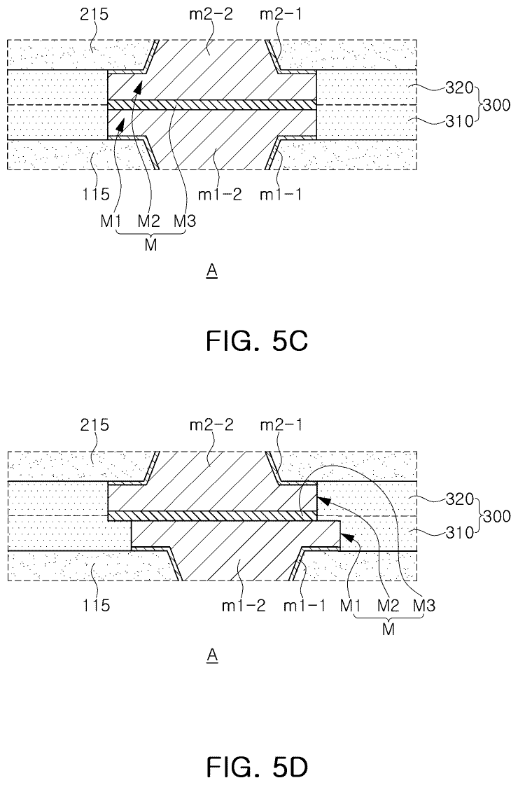

FIGS. 5A to 5D are enlarged cross-sectional diagrams illustrating various examples of hybrid metal bonding.

Referring to FIG. 5A, an upper surface of the first metal layer M1 and a lower surface of the second metal layer M2 may be directly bonded to each other. The first and second metal layers M1 and M2 may be directly bonded to each other and may form a metal layer M. A boundary between the first and second metal layers M1 and M2 may be distinct. The first metal layer M1 may include a 1-1 metal layer m1-1, which is a seed layer, and a 1-2 metal layer m1-2, which is a plating layer. The second metal layer M2 may also include a 2-1 metal layer m2-1, which is a seed layer, and a 2-2 metal layer m2-2, which is a plating layer. Each of the component may include the metals described above, preferably copper (Cu), but an embodiment example thereof is not limited thereto. The insulating layer 300 may include first and second insulating films 310 and 320. Each of the first and second insulating films 310 and 320 may include an inorganic insulating film. Each of the first and second insulating films 310 and 320 may include an inorganic insulating material, preferably SiO₂, but an embodiment example thereof is not limited thereto. The first insulating film 310 may be disposed on an upper side of the first substrate 100 and may cover at least a portion of a side surface of the first metal layer M1. The second insulating film 320 may be disposed on a lower side of the second substrate 200 and may cover at least a portion of a side surface of the second metal layer M2. A boundary between the first and second insulating films 310 and 320 may be indistinct, and may be integrated with each other, for example. The first and second metal layers M1 and M2 and the first and second insulating films 310 and 320 may be bonded to each other through hybrid metal bonding. An upper surface of the first metal layer M1 and an upper surface of the first insulating film 310 may be substantially coplanar with each other, and a lower surface of the second metal layer M2 and a lower surface of the second insulating film 320 may be substantially coplanar with each other, but an embodiment example thereof is not limited thereto. This bonding structure may be applied to the printed circuit board 500A according to the aforementioned example and the printed circuit board 600A according to the modified example. Also, the structure may also be applied to printed circuit boards 500B, 500C, and 500D according to other examples described later and printed circuit boards 600B, 600C, and 600D according to modified examples.

Referring to FIG. 5B, the first metal layer M1 and the second metal layer M2 may be bonded such that respective side surfaces thereof may be disposed to be shifted from each other. For example, at least a portion of a side surface of metal layer M may have a step difference. Here, the step difference may include the step difference between vertical side surfaces, and also the step difference between curved side surfaces including outwardly curved or inwardly curved shapes. For example, even when a side surface of metal layer M is almost S-shaped, when an upper end and a lower end of the metal layer M are sufficiently shifted from each other, a step difference may be formed. For example, the step difference may refer to the step difference caused by misalignment between the first and second metal layers M1 and M2 during bonding, and may be distinguished from simply unevenness formed on the side surface, such as surface roughness. In this case, the insulating layer 300 may cover at least a portion of each of the upper surface of the first metal layer M1 and the lower surface of the second metal layer M2. Accordingly, improved adhesive force may be obtained. Also, reliability may be further improved. Other descriptions may be the same as the descriptions of the bonding structure described with reference to FIG. 5A. The bonding structure may also be applied to the printed circuit board 500A according to the aforementioned example and the printed circuit board 600A according to the modified example. Also, the structure may also be applied to printed circuit boards 500B, 500C, and 500D according to other examples described later and printed circuit boards 600B, 600C, and 600D according to modified examples.

Referring to FIG. 5C, an upper surface of the first metal layer M1 and a lower surface of the second metal layer M2 may be bonded to each other through a third metal layer M3 including a different metal from the first and second metal layers M1 and M2. For example, a heterogeneous metal layer M3 may be disposed in the metal layer M. For example, the first and second metal layers M1 and M2 may include copper (Cu), and the third metal layer M3 may include silver (Ag) or gold (Au), but an embodiment example thereof is not limited thereto. When the third metal layer M3 is used, adhesive force between the first and second metal layers M1 and M2 may be improved. Other descriptions may be the same as the descriptions of the bonding structure described with reference to FIG. 5A. The bonding structure may also be applied to the printed circuit board 500A according to the aforementioned example and the printed circuit board 600A according to the modified example. Also, the structure may also be applied to printed circuit boards 500B, 500C, and 500D according to other examples described later and printed circuit boards 600B, 600C, and 600D according to modified examples.

Referring to FIG. 5D, an upper surface of the first metal layer M1 and a lower surface of the second metal layer M2 may be bonded to each other through the third metal layer M3 including a metal different from that of the first and second metal layers M1 and M2. For example, a heterogeneous metal layer M3 may be disposed in the metal layer M. For example, the first and second metal layers M1 and M2 may include copper (Cu), and the third metal layer M3 may include silver (Ag) or gold (Au). In this case, adhesive force between the first and second metal layers M1 and M2 may be improved. Also, the first metal layer M1 and the second metal layer M2 may be bonded to each other such that respective side surfaces thereof may be shifted from each other. For example, at least a portion of the side surface of the metal layer M may have a step difference. Here, the step difference may include the step difference between vertical side surfaces, and also the step difference between curved side surfaces including outwardly curved or inwardly curved shapes. For example, even when the side surface of the metal layer M is almost S-shaped, when the upper end and the lower end of metal layer M are sufficiently shifted from each other, a step difference may be obtained. For example, the step difference may refer to the step difference formed by misalignment between the first and second metal layers M1 and M2 during bonding, and may be distinguished from simply unevenness formed on the side surface, such as surface roughness. In this case, the insulating layer 300 may cover at least a portion of the upper surface of the first metal layer M1 and the lower surface of the second metal layer M2, and may thus have improved adhesive force and reliability. Also, at least a portion of the third metal layer M3 may be disposed to deviate from at least one of the upper surface of the first metal layer M1 and the lower surface of the second metal layer M2. For example, a portion of the third metal layer M3 may be disposed to extend beyond the upper surface of the first metal layer M1, and in this case, a portion of the lower surface of the third metal layer M3 may be in contact with the insulating layer 300. Thus, adhesive force may be improved. Alternatively, for example, a portion of the third metal layer M3 may be disposed to extend beyond the lower surface of the second metal layer M2, and in this case, a portion of the upper surface of the third metal layer M3 may be in contact with the insulating layer 300 such that adhesive force may be improved. Other descriptions may be the same as descriptions of the bonding structure in FIG. 5A. The bonding structure may also be applied to the printed circuit board 500A according to the aforementioned example and the printed circuit board 600A according to the modified example. Also, the structure may also be applied to printed circuit boards 500B, 500C, and 500D according to other examples described later and printed circuit boards 600B, 600C, and 600D according to modified examples.

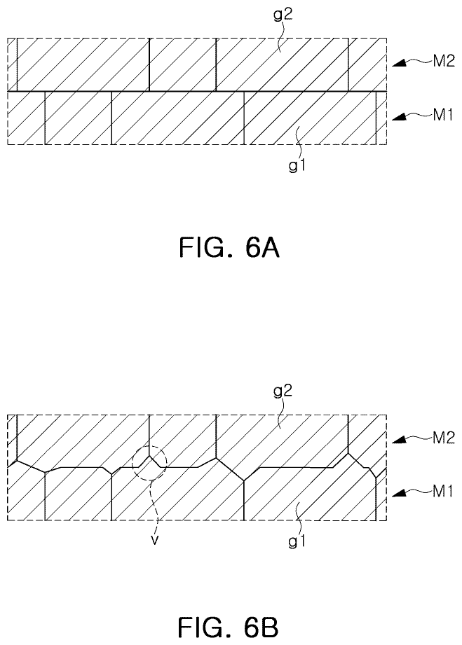

FIGS. 6A and 6B are enlarged cross-sectional diagrams illustrating various examples of a boundary surface in intermetallic bonding.

Referring to FIG. 6A, in the case in which the first metal layer M1 and the second metal layer M2 are directly bonded to each other by hybrid metal bonding, the first metal layer M1 and the second metal layer M2 may have a plurality of first and second grains g1 and g2, respectively. In this case, in the intermetallic bonding boundary surface of the first and second metal layers M1 and M2, the plurality of first grain g1 and the plurality of second grain g2 may include a plurality of triple junctions, for example, at approximately 90 degrees. The bonding structure may be applied to the printed circuit board 500A according to the aforementioned example and the printed circuit board 600A according to the modified example. Also, the structure may also be applied to printed circuit boards 500B, 500C, and 500D according to other examples described later and printed circuit boards 600B, 600C, and 600D according to modified examples.

Referring to FIG. 6B, a boundary surface of intermetallic bonding may have a diffusion wedge due to a decrease in surface energy of a grain boundary. For example, a boundary surface between an upper surface of the first metal layer M1 and a lower surface of the second metal layer M2 may have at least one protrusion v protruding inwardly of the first metal layer M1 and the second metal layer M2, and the protrusion v may include a diffusion wedge caused by diffusion of metal particles. For example, in the intermetallic bonding boundary surface of the first and second metal layers M1 and M2, the plurality of first grain g1 and the plurality of second grain g2 may include a plurality of triple junctions, for example, approximately 120 degrees. The bonding structure may also be applied to the printed circuit board 500A according to the aforementioned example and the printed circuit board 600A according to the modified example. Also, the structure may also be applied to printed circuit boards 500B, 500C, and 500D according to other examples described later and printed circuit boards 600B, 600C, and 600D according to modified examples.

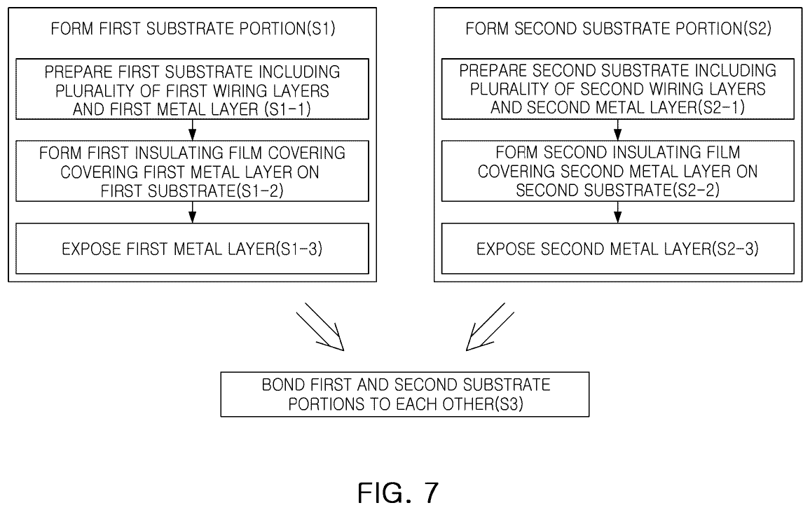

FIG. 7 is a diagram illustrating an example of a method of manufacturing a printed circuit board.

Referring to the drawings, the method of manufacturing a printed circuit board according to an example may include forming a first substrate portion (S1), forming a second substrate portion (S2), and bonding the first and second substrate portions to each other (S3). The forming the first substrate portion (S1) may include preparing a first substrate including a plurality of first wiring layers and a first metal layer (S1-1), forming a first insulating film covering the first metal layer on the first substrate (S1-2), and exposing the first metal layer (S1-3). The forming the second substrate portion (S2) may include preparing a second substrate including a plurality of second wiring layers and a second metal layer (S2-1), forming a second insulating film covering the second metal layer on the second substrate (S2-2), and exposing the second metal layer (S2-3).

In the description below, the method of manufacturing a printed circuit board according to an example may be described in greater detail with reference to the drawings.

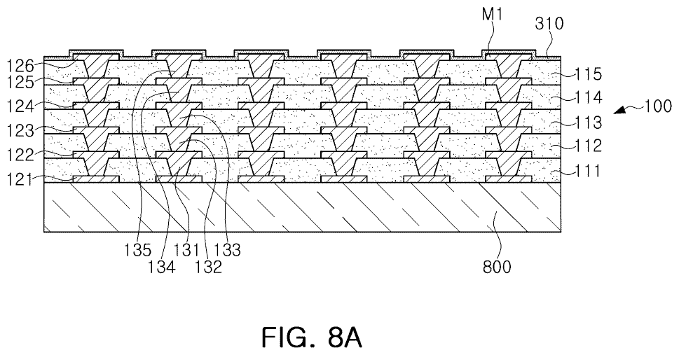

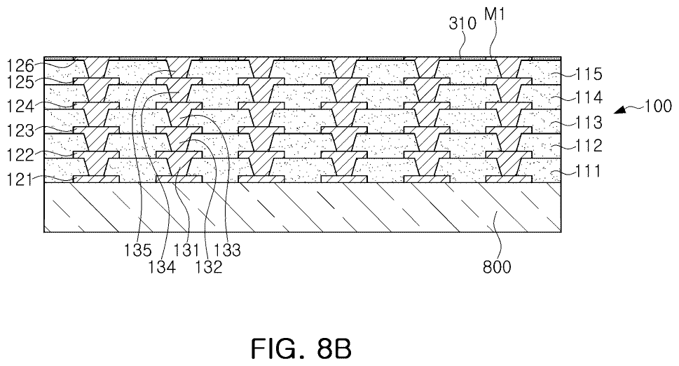

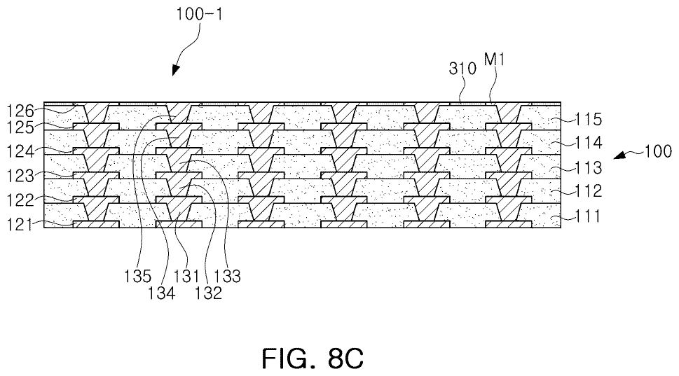

FIGS. 8A to 8C are cross-sectional diagrams illustrating processes of an example of a method of manufacturing a first substrate portion.

Referring to FIG. 8A, a first substrate 100 including a plurality of first wiring layers 121, 122, 123, 124, 125, and 126 and having a first metal layer M1 formed on one side may be prepared. The first substrate 100 may be a multilayer substrate as described above. The first substrate 100 may be formed through a substrate process, for example, an ETS process and a build-up process on a carrier 800. Thereafter, a first insulating film 310 covering at least a portion of the first metal layer M1 may be formed on one side of the first substrate 100. The first insulating film 310 may be an inorganic insulating film as described above. The first insulating film 310 may be formed through a coating process such as deposition. The first insulating film 310 may conformally cover the first substrate 100 and the first metal layer M1.

Referring to FIG. 8B, the first metal layer M1 and the first insulating film 310 may be planarized and may expose a surface of the first metal layer M1. As the flattening process, grinding may be used. Through the planarization process, thicknesses of the first metal layer M1 and the first insulating film 310 may become substantially the same. Also, a thickness of the first metal layer M1 may be smaller than a thickness of each of the other 1-1, 1-2, 1-3, 1-4, and 1-5 wiring layers 121, 122, 123, 124, and 125.

Referring to FIG. 8C, the carrier 800 may be separated. The carrier 800 may be physically detached, but an embodiment example thereof is not limited thereto. After the carrier 800 is removed, an etching process for removing the remaining metal film from the carrier 800 may be performed, and in the process, a recess step difference may be formed in the 1-1 wiring layer 121, but an embodiment example thereof is not limited thereto, and a recess step difference may also be prevented.

Through a series of processes, the first substrate portion 100-1 may be prepared. Other descriptions may be substantially the same as the descriptions of the printed circuit board 500A according to the aforementioned example, and overlapping descriptions will not be provided.

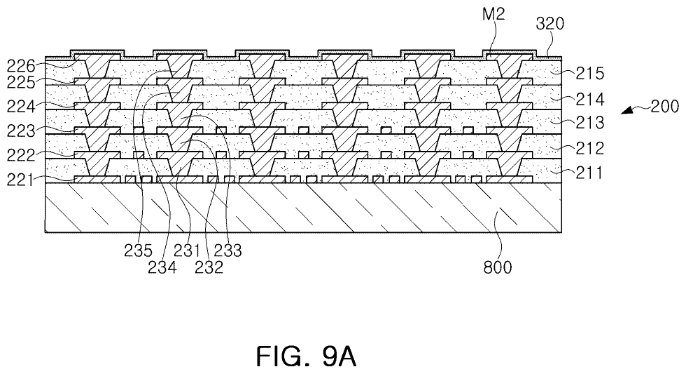

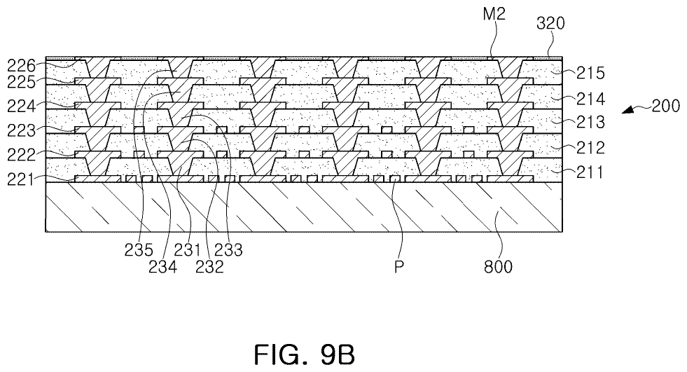

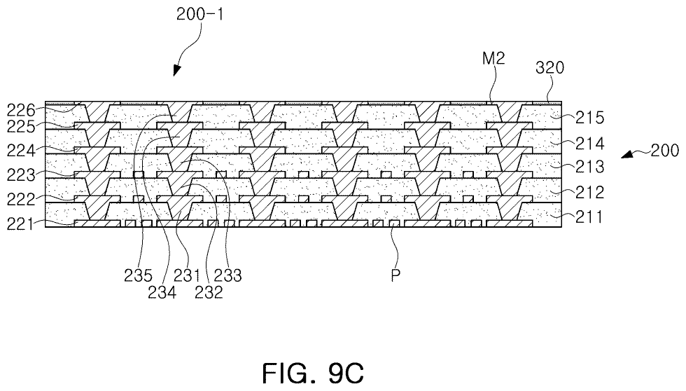

FIGS. 9A to 9C are cross-sectional diagrams illustrating processes of an example of a method of manufacturing a second substrate portion.

Referring to FIG. 9A, a second substrate 200 including a plurality of second wiring layers 221, 222, 223, 224, 225, and 226 and having a second metal layer M2 formed on one side may be prepared. As described above, the second substrate 200 may be configured as a multilayer substrate including a fine circuit pattern P having a line width of a wiring line and a distance between wiring lines smaller than those of a wiring of each of the plurality of first wiring layers 121, 122, 123, 124, 125, and 126 of the first substrate 100. The second substrate 200 may be formed through a substrate process, such as an ETS process and a build-up process on carrier 800. Thereafter, a second insulating film 320 covering at least a portion of the second metal layer M2 may be formed on one side of the second substrate 200. The second insulating film 320 may be an inorganic insulating film as described above. The second insulating film 320 may be formed through a coating process such as deposition. The second insulating film 320 may conformally cover the second substrate 200 and the second metal layer M2.

Referring to FIG. 9B, the second metal layer M2 and the second insulating film 320 may be planarized and may expose a surface of the second metal layer M2. As the flattening process, grinding may be used. Through the planarization process, thicknesses of the second metal layer M2 and the second insulating film 320 may become substantially the same. Also, a thickness of the second metal layer M2 may be smaller than a thickness of each of the other 2-1, 2-2, 2-3, 2-4, and 2-5 wiring layers 221, 222, 223, 224, and 225.

Referring to FIG. 9C, the carrier 800 may be separated. The carrier 800 may be physically detached, but an embodiment example thereof is not limited thereto. After the carrier 800 is removed, an etching process for removing the other metal film from the carrier 800 may be performed, and in the process, a recess step difference may be formed in the 2-1 wiring layer 221 if desired, but an embodiment example thereof is not limited thereto, and a recess step difference may be prevented.

Through a series of processes, the second substrate portion 200-1 may be prepared. Other descriptions may be substantially the same as the descriptions of the printed circuit board 500A according to the aforementioned example, and overlapping descriptions will not be provided.

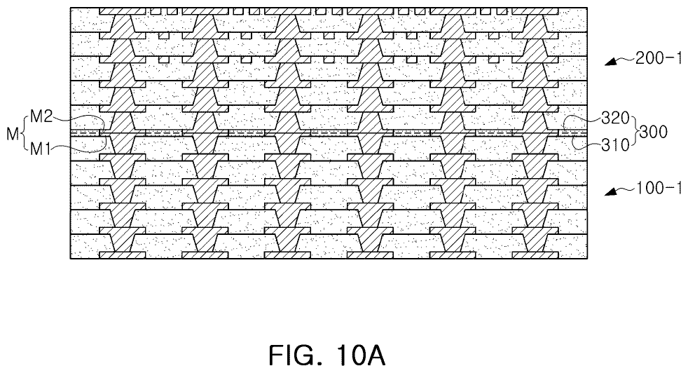

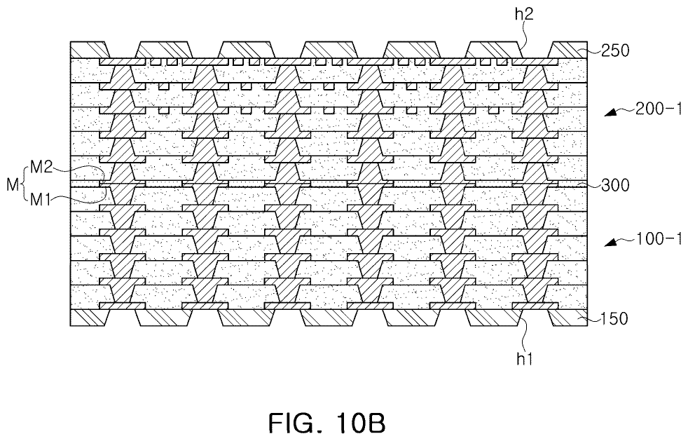

FIGS. 10A and 10B are cross-sectional diagrams illustrating an example of bonding first and second substrate portions.

Referring to FIG. 10A, the first and second substrates portions 100-1 and 200-1 may be bonded to each other by bonding the first and second insulating films 310 and 320 to each other and bonding the first and second metal layers M1 and M2 to each other. Hybrid metal bonding, described later, may be used for bonding the first and second insulating films 310 and 320 and the first and second metal layers M1 and M2 to each other.

Referring to FIG. 10B, first and second resist layers 150 and 250 may be formed on both sides of the bonded first and second substrates portions 100-1 and 200-1. Also, a plurality of first and second openings h1 and h2 may be formed on the first and second resist layers 150 and 250, respectively.

Through a series of processes, the printed circuit board 500A according to the aforementioned example may be manufactured. Other descriptions may be substantially the same as the descriptions of the printed circuit board 500A according to the aforementioned example, and overlapping descriptions will not be provided.

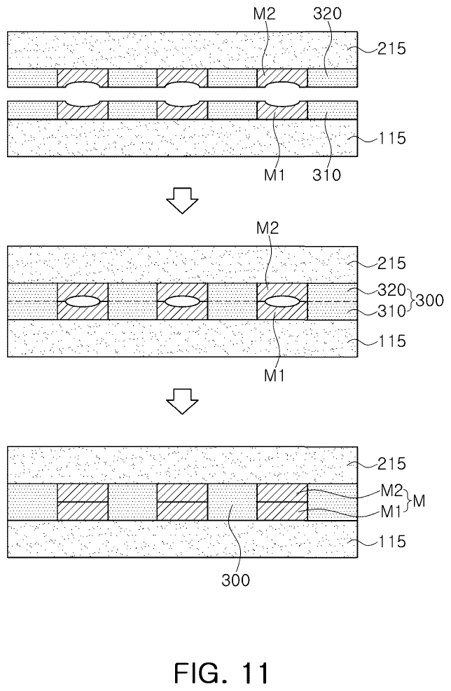

FIG. 11 is cross-sectional diagrams illustrating hybrid metal bonding.

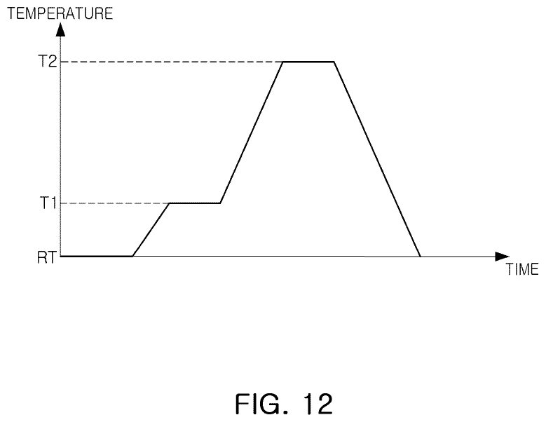

FIG. 12 is a graph indicating a temperature cycle of hybrid metal bonding according to an example embodiment.

Referring to the drawing, first and second insulating films 310 and 320 may be in contact with each other, and also first and second metal layers M1 and M2 may be in contact with each other. Before contact, surfaces of the first and second insulating films 310 and 320 and the first and second metal layers M1 and M2 may be treated by wet cleaning or plasma activation. In this case, an inwardly curved recess may be formed on a surface of each of the first and second metal layers M1 and M2. The first and second insulating films 310 and 320 and the first and second metal layers M1 and M2 may be in contact with each other at room temperature RT. Thereafter, the first and second insulating films 310 and 320 may be bonded to each other at a first temperature. For example, at the first temperature T1, the first and second insulating films 310 and 320 may be directly bonded to each other and may be integrated into the insulating layer 300. The first temperature T1 may be lower than a second temperature T2. Thereafter, the first and second metal layers M1 and M2 may be bonded to each other at a second temperature T2. For example, at the second temperature T2, the first and second metal layers M1 and M2 may be directly bonded to each other and a metal layer M may be formed. For example, during an annealing process at the second temperature T2, each metal may be directly bonded to each other by increasing a grain size. The second temperature T2 may be a higher temperature than the first temperature T1.

Through a series of processes, the aforementioned first and second substrates portions 100-1 and 100-2 may be bonded to each other. Other descriptions may be substantially the same as descriptions of the printed circuit board 500A according to the aforementioned example, and overlapping descriptions will not be provided.

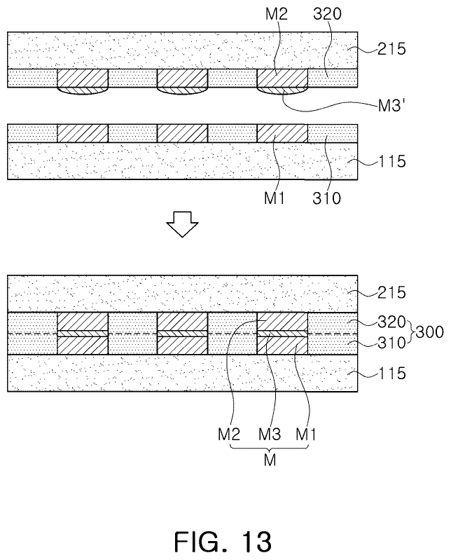

FIG. 13 is cross-sectional diagrams illustrating another example of hybrid metal bonding.

Referring to the drawing, the bonding the aforementioned first and second substrates portions 100-1 and 100-2 to each other may further include applying metal paste M3′ including a metal different from that of the first and second metal layers M1 and M2 between the first and second metal layers M1 and M2. For example, before allowing the first and second insulating films 310 and 320 and the first and second metal layers M1 and M2 to be in contact with each metal other, metal paste M3′ may be applied on an upper surface of the first metal layer M1 and/or a lower surface of the second metal layer M2. Thereafter, through the aforementioned thermal compression process, the first and second insulating films 310 and 320 may be bonded directly to each other, and the first and second metal layers M1 and M2 may also be bonded to each other through the third metal layer M3. Accordingly, an insulating layer 300 and a metal layer M may be formed.

Through a series of processes, the aforementioned first and second substrates portions 100-1 and 100-2 may be bonded to each other. Other descriptions may be substantially the same as descriptions of the printed circuit board 500A according to the aforementioned example, and overlapping descriptions will not be provided.

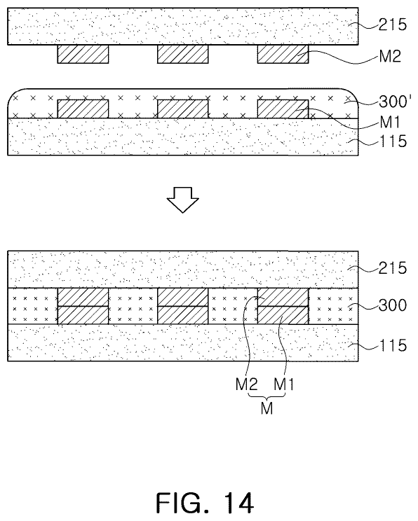

FIG. 14 is cross-sectional diagrams illustrating another example of hybrid metal bonding.

Referring to the drawing, the first and second metal layers M1 and M2 may be formed of nano-twinned copper instead of general copper, and the insulating layer 300 may be formed of non-conductive paste. For example, the non-conductive paste 300′ may be applied on the first metal layer M1 formed of a nano-twinned copper film, the second metal layer M2 formed of a nano-twinned copper film may be pressed thereon, may be bonded at a high temperature, and the first and second metal layers M1 and M2 may be bonded directly to each other. Alternatively, the non-conductive paste 300′ may be applied on the second metal layer M2 formed of a nano-twinned copper film, the first metal layer M1 formed of a nano-twinned copper film may be pressed thereon, may be bonded at a high temperature and the first and second metal layers M1 and M2 may be bonded directly to each other. Accordingly, the metal layer M2 and the insulating layer 300 burying the same may be formed. If desired, the non-conductive paste 300′ may be applied while the first insulating film 310 and/or the second insulating film 320 described above are formed, and in this case, the insulating layer 300 may include a first insulating film 310 and/or a second insulating film 320.

Through a series of processes, the aforementioned first and second substrates portions 100-1 and 100-2 may be bonded to each other. Other descriptions may be substantially the same as descriptions of the printed circuit board 500A according to the aforementioned example, and overlapping descriptions will not be provided.

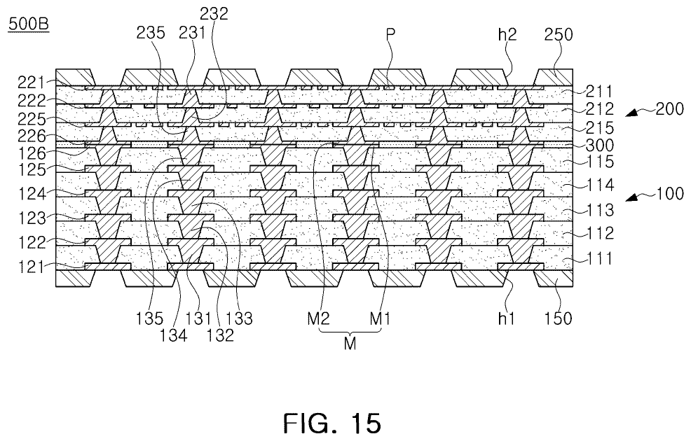

FIG. 15 is a cross-sectional diagram illustrating another example of a printed circuit board.

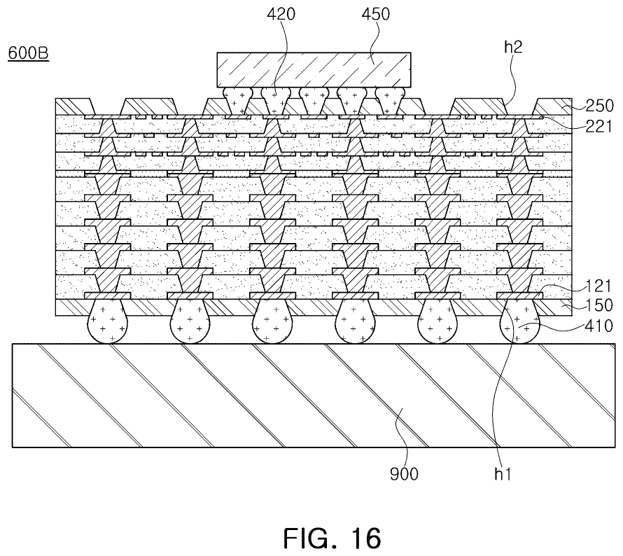

FIG. 16 is a cross-sectional diagram illustrating a modified example of the printed circuit board in FIG. 15.

Referring to the drawings, differently from the printed circuit board 500A according to the aforementioned example and the printed circuit board 600A according to the modified example, in the printed circuit board 500B according to another example and the printed circuit board 600B according to the modified example, a first substrate 100 and a second substrate 200 may have an asymmetric structure. For example, a thickness of the second substrate 200 may be smaller than that of the first substrate 100. For example, the number of the plurality of second insulating layers 211, 212, and 215 may be less than the number of the plurality of first insulating layers 111, 112, 113, 114, and 115, and an overall thickness of the plurality of second insulating layers 211, 212, and 215 may also be smaller. Also, the number of the plurality of second wiring layers 221, 222, 223, and 226 may be less than the number of the plurality of first wiring layers 121, 122, 123, 124, 125, and 126. Also, the number of the plurality of second via layers 231, 232, and 235 may be less than the number of the plurality of first via layers 131, 132, 133, 134, 135, and 136. Thicknesses of the plurality of 2-1, 2-2, and 2-5 insulating layers 211, 212, 215 may be smaller than those of the plurality of 1-1, 1-2, 1-3, 1-4, and 1-5 insulating layers 111, 112, 113, 114, and 115. Also, thicknesses of the plurality of 2-1, 2-2, 2-3, 2-6 wiring layers 221, 222, 223, and 226 may be smaller than those of the plurality of 1-1, 1-2, 1-3, 1-4, and 1-5, 1-6 wiring layer 121, 122, 123, 124, 125, and 126. Also, widths of upper ends and widths of lower ends of the plurality of 2-1, 2-2, 2-5 via layers 231, 232, and 235 may smaller than those of the plurality of 1-1, 1-2, 1-3, 1-4, and 1-5 via layer 131, 132, 133, 134, and 135. Wirings of the plurality of 2-1, 2-2, 2-3, and 2-6 wiring layers 221, 222, 223, and 226 may have a finer pitch than those of wirings of the plurality of 1-1, 1-2, 1-3, 1-4, and 1-5, 1-6 wiring layer 121, 122, 123, 124, 125, and 126. Also, a via of each of the plurality of 2-1, 2-2, and 2-5 via layer 231, 232, and 235 may have a finer pitch than those of vias of the plurality of 1-1, 1-2, 1-3, 1-4, and 1-5 via layer 131, 132, 133, 134, and 135. For example, the first and second substrates 100 and 200 may have an asymmetric structure with different numbers of layers.

Other descriptions may be substantially the same as descriptions of the printed circuit board 500A according to the aforementioned example and the printed circuit board 600A according to the modified example. Accordingly, overlapping descriptions will not be provided.

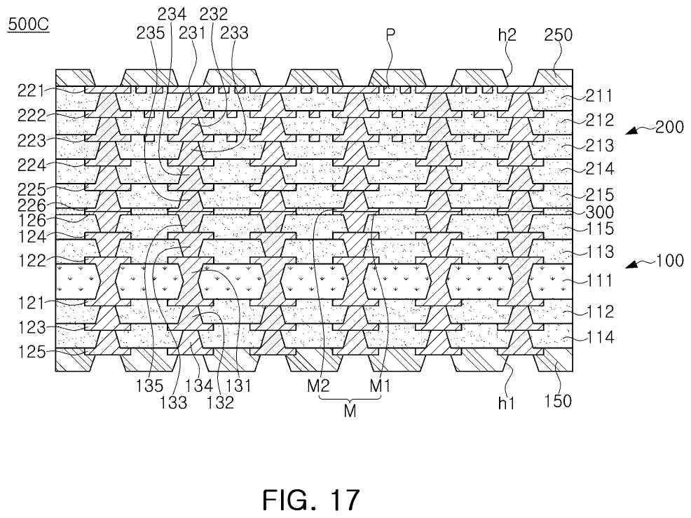

FIG. 17 is a cross-sectional diagram illustrating another example of a printed circuit board.

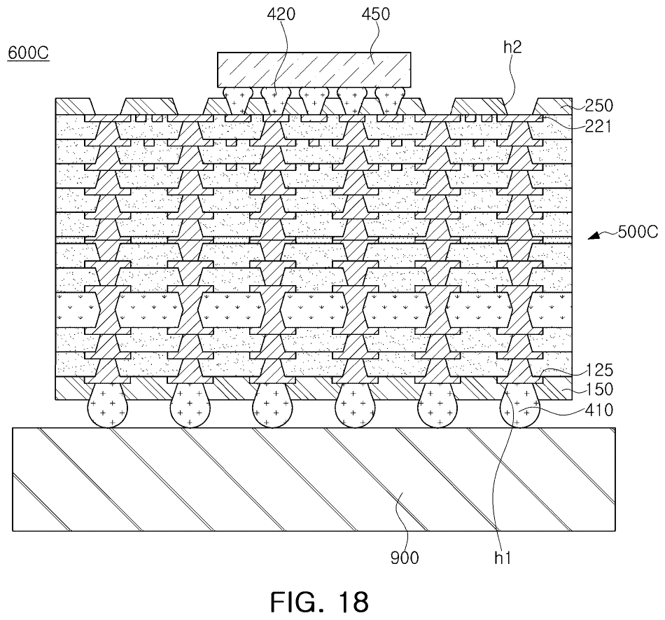

FIG. 18 is a cross-sectional diagram illustrating a modified example of the printed circuit board in FIG. 17.

Referring to the drawings, differently from the printed circuit board 500A according to the aforementioned example and the printed circuit board 600A according to the modified example, in the printed circuit board 500C according to another example and the printed circuit board 600C according to the modified example, the first substrate 100 may be a core-type multilayer printed circuit board rather than a coreless type multilayer printed circuit board. For example, the first substrate 100 may include a 1-1 insulating layer 111, 1-1 and 1-2 wiring layers 121, 122 disposed on a lower surface and an upper surface of the 1-1 insulating layer 111, respectively, a first via layer 131 penetrating the 1-1 insulating layer 111 and connecting 1-1 and 1-2 wiring layers 121 and 122 to each other, a 1-2 insulating layer 112 disposed on a lower surface of 1-1 insulating layer 111 and covering the 1-1 wiring layer 121, a 1-3 wiring layer 123 disposed on a lower surface of 1-2 insulating layer 112, a second via layer 132 penetrating the 1-2 insulating layer 112 and connecting the 1-1 and 1-3 wiring layers 121 and 123 to each other, a 1-3 insulating layer 113 disposed on an upper surface of the 1-1 insulating layer 111 and covering the 1-2 wiring layer 122, a 1-4 wiring layer 124 disposed on an upper surface of the 1-3 insulating layer 113, a third via layer 133 penetrating the 1-3 insulating layer 113 and connecting the 1-2 and 1-4 wiring layers 122 and 124 to each other, a 1-4 insulating layer 114 disposed on a lower surface of the 1-2 insulating layer 112 and covering the 1-3 wiring layer 123, a fourth via layer 134 penetrating the 1-5 wiring layer 125 and the 1-4 insulating layer 114 disposed on a lower surface of the 1-4 insulating layer 114 and connecting the 1-3 and 1-5 wiring layers 123 and 125 to each other, a 1-5 insulating layer 115 disposed on an upper surface of the 1-3 insulating layer 113 and covering the 1-4 wiring layer 124, a 1-6 wiring layer 126 disposed on an upper surface of the 1-5 insulating layer 115, and a fifth via layer 135 penetrating the 1-5 insulating layer 115 and connecting the 1-4 and 1-6 wiring layers 124 and 126 to each other. The first insulating film 310 may be disposed on the upper surface of the 1-5 insulating layers 115 and may cover at least a portion of the first metal layer M1. The first resist layer 150 may be disposed on the lower surface of the 1-4 insulating layer 114 and may cover at least a portion of the 1-5 wiring layer 125. The plurality of first openings h1 may expose at least a portion of each of the 1-5 wiring layers 125. As described above, the first substrate 100, a low-density substrate having relatively small wiring density, may be manufactured as a core-type multilayer printed circuit board, and the second substrate 200, a high-density substrate having relatively high wiring density, may be manufactured as a coreless type multilayer printed circuit board. The 1-1 insulating layer 111 may be a core layer, and the 1-2, 1-3, 1-4, and 1-5 insulating layers 112, 113, 114, and 115 may be build-up layers. The 1-1 insulating layer 111 may have a thickness greater than those of the 1-2, 1-3, 1-4, and 1-5 insulating layers 112, 113, 114, and 115. The 1-1 insulating layer 111 may include copper clad laminate (CCL), and each of the 1-2, 1-3, 1-4, and 1-5 insulating layers 112, 113, 114, and 115 may include Ajinomoto build-up film (ABF) or prepreg (PPG), but an embodiment example thereof is not limited thereto. The 1-1 insulating layer 111 may include types of insulating materials other than organic insulating materials such as glass and ceramic. If desired, the component may also include a metal covered with an insulating film. The 1-1 via layer 131 may have an hourglass shape or a pillar shape in a cross-section. Also, the 1-2 and 1-4 via layers 132 and 134 may have a tapered shape of which a width of a lower end may be greater than a width of an upper end in a cross-section. Also, the 1-3 and 1-5 via layers 133 and 135 may have a tapered shape of which a width of a lower end may be less than a width of an upper end in a cross-section. However, an embodiment example thereof is not limited thereto, and various forms of via structures may be applied.

Other descriptions may be substantially the same as descriptions of the printed circuit board 500A according to the aforementioned example and the printed circuit board 600A according to the modified example. Accordingly, overlapping descriptions will not be provided.

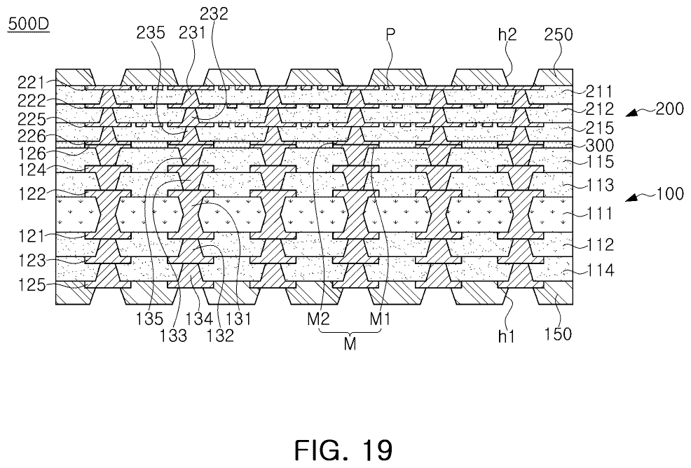

FIG. 19 is a cross-sectional diagram illustrating another example of a printed circuit board.

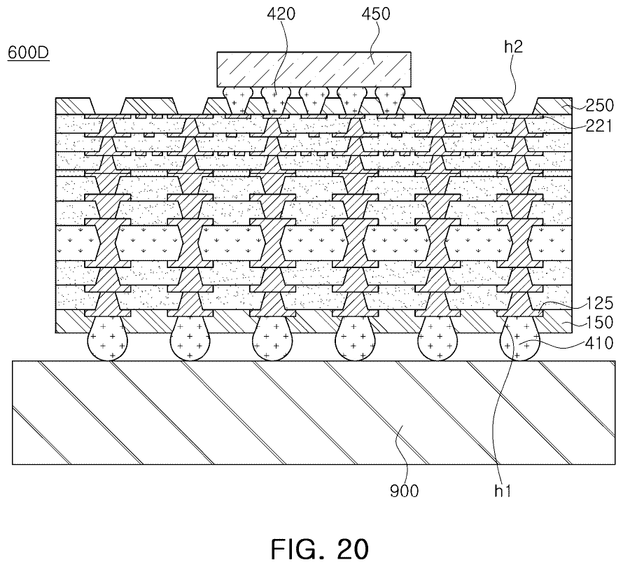

FIG. 20 is a cross-sectional diagram illustrating a modified example of the printed circuit board in FIG. 19.

Referring to the drawings, differently from the printed circuit board 500C according to another example described above and printed circuit board 600C according to the modified example, in the printed circuit board 500D according to another example and printed circuit board 600D according to the modified example, the first substrate 100 and the second substrate 200 may have asymmetric structure in various forms. For example, the first substrate 100 may be a core-type multilayer printed circuit board, the second substrate 200 may be a coreless type multilayer printed circuit board, the number of the plurality of second insulating layer 211, 212, and 215 may be less than the number of the plurality of first insulating layer 111, 112, 113, 114, and 115, and overall thicknesses may also be smaller. Also, the number of the plurality of second wiring layers 221, 222, 223, and 226 may be less than the number of the plurality of first wiring layers 121, 122, 123, 124, 125, and 126. Also, the number of the plurality of second via layers 231, 232, and 235 may be less than the number of the plurality of first via layers 131, 132, 133, 134, 135, and 136. Also, a thickness of the second substrate 200 may be smaller than that of the first substrate 100. The plurality of 2-1, 2-2, and 2-5 insulating layers 211, 212, and 215 may have thicknesses smaller than those of the plurality of 1-1, 1-2, 1-3, 1-4, and 1-5 insulating layers 111, 112, 113, 114, and 115. Also, the plurality of 2-1, 2-2, 2-3, and 2-6 wiring layers 221, 222, 223, and 226 may have thicknesses smaller than those of the plurality of 1-1, 1-2, 1-3, 1-4, 1-5, and 1-6 wiring layers 121, 122, 123, 124, 125, and 126. Also, widths of upper ends and widths of lower ends of the plurality of 2-1, 2-2, 2-5 via layers 231, 232, and 235 may be smaller than those of the plurality of 1-1, 1-2, 1-3, and 1-4, and 1-5 via layer 131, 132, 133, 134, and 135. Wirings of the plurality of 2-1, 2-2, 2-3, and 2-6 wiring layers 221, 222, 223, and 226 may have a finer pitch than that of the plurality of 1-1, 1-2, 1-3, 1-4, 1-5, and 1-6 wiring layers 121, 122, 123, 124, 125, and 126. Also, vias of the plurality of 2-1, 2-2, and 2-5 via layer 231, 232, and 235 may have a finer pitch than that of the plurality of 1-1, 1-2, 1-3, 1-4, and 1-5 via layer 131, 132, 133, 134, and 135. For example, the first and second substrates 100 and 200 may have different asymmetric structures with different numbers of layers.

Other descriptions may be the same as those of the printed circuit board 500A according to the aforementioned example, the printed circuit board 600A according to the modified example, the printed circuit board 500C according to another example described above and the printed circuit board 600C according to the modified example. Accordingly, overlapping descriptions will not be provided.

According to the aforementioned example embodiments, a multilayer printed circuit board including a fine circuit may be provided.

Also, a printed circuit board which may reduce manufacturing costs by high yield and a process efficiency may be provided.

In the present disclosure, the term “covering” may include the configuration in which the component is entirely covered and at least a portion of the component is covered, or the component is directly or indirectly covered. Also, the term “fill” may include the configuration in which the component is completely filled, and also at least a portion of the component is filled, and the component is almost filled. For example, a void may be present. Also, the term “surrounding” may include the configuration in which the component is completely surrounded, and is also almost surrounded. Also, the term “exposing” may include the configuration in which the component is completely exposed or a portion thereof is exposed, and the exposing may refer to exposing from the buried component. For example, the configuration in which the opening may expose a pad may include exposing a pad from the resist layer, and a surface treatment layer may be further disposed on the exposed pad.

In the example embodiment, the configuration in which the component is disposed in a through-portion or a through-hole may include the configuration in which the component is completely disposed in the through-portion or through-hole, and also the configuration in which the component partially protrudes to an upper side or a lower side on a cross-section. For example, in the case in which the component is disposed in a through-portion or through-hole on a plane, the configuration may be understood in a broader sense.

In the present disclosure, the term “cross-section” refers to the cross-sectional shape when the object is cut vertically, or the cross-sectional shape when the object is cut vertically, or the cross-sectional shape when the object is viewed from the side. Also, the configuration in which the components are on a plane may indicate a planar shape when the object is cut horizontally, or a planar shape when the object is viewed from above or below.

In the present disclosure, the terms “lower side,” “lower portion,” and “lower surface” may be used to refer to a downward direction based on the cross-section of the drawing, and “upper side,” “upper portion,” “upper surface” may be used to refer to the opposite direction. However, this direction is defined for ease of description, and the scope of the patent claims is not particularly limited by the description of the direction, and the terms “upper and lower sides” may be relative terms.

In the example embodiments, the term “connected” may not only refer to “directly connected” but also include “indirectly connected” by may refer to of an adhesive layer, or the like. Also, the term “electrically connected” may include both the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

A thickness, width, length, depth, line width, distance, pitch, and the like, may be measured using a scanning microscope or an optical microscope based on a cross section of a printed circuit board which may be polished or cut. The cross-section may be a vertical cross-section or a horizontal cross-section, and each value may be measured based on the required cross-section. For example, a width of an upper end and/or lower end of a via may be measured on a cross-section cut along a central axis of the via. In this case, when the value is not constant, the value may be determined as an average value of the values measured at five random points. A minimum value may be determined as the smallest value measured on the corresponding layer or region.

In the example embodiments, the term “example embodiment” may not refer to one same example embodiment, and may be provided to describe and emphasize different unique features of each example embodiment. The above suggested example embodiments may be implemented do not exclude the possibilities of combination with features of other example embodiments. For example, even though the features described in an example embodiment are not described in the other example embodiment, the description may be understood as relevant to the other example embodiment unless otherwise indicated.

An expression used in the singular encompasses the expression of the plural, unless it has a clearly different meaning in the context.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a first substrate including a first wiring layer;
a second substrate disposed on the first substrate and including a second wiring layer;
a metal layer disposed between the first and second substrates; and
a bonding layer disposed between the first and second substrates;
wherein each of the first and second substrates includes an organic material, and
wherein the bonding layer includes an inorganic material.

2. The printed circuit board of claim 1,
wherein the metal layer includes a first metal layer disposed on an uppermost side of the first substrate and a second metal layer disposed on a lowermost side of the second substrate.

3. The printed circuit board of claim 2,
wherein the first and second metal layers are bonded to each other such that side surfaces thereof are disposed to be shifted from each other.

4. The printed circuit board of claim 2, wherein an upper surface of the first metal layer and a lower surface of the second metal layer are directly bonded to each other.

5. The printed circuit board of claim 4, wherein a boundary surface between the upper surface of the first metal layer and the lower surface of the second metal layer has at least one protrusion protruding inwardly of the first and second metal layers.

6. The printed circuit board of claim 5, wherein the protrusion includes a diffusion wedge of metal particles.

7. The printed circuit board of claim 2, wherein the metal layer further includes a third metal layer disposed between the first and second metal layers and including a metal different from that of the first and second metal layers.

8. The printed circuit board of claim 7, wherein at least a portion of the third metal layer is disposed beyond at least one of an upper surface of the first metal layer and a lower surface of the second metal layer.

9. The printed circuit board of claim 7,
wherein each of the first and second metal layers includes copper (Cu), and
wherein the third metal layer includes silver (Ag) or gold (Au).

10. The printed circuit board of claim 1, wherein the bonding layer includes an inorganic insulating film.

11. The printed circuit board of claim 10, wherein the inorganic insulating film includes SiO₂, SiN or SiCN.

12. The printed circuit board of claim 1,
wherein the first substrate includes a plurality of first insulating layers, a plurality of first wiring layers disposed on or in the plurality of first insulating layers, and a plurality of first via layers penetrating at least one of the plurality of first insulating layers, respectively, and
wherein the second substrate includes a plurality of second insulating layer, a plurality of second wiring layers disposed on or in the plurality of second insulating layers, respectively, and a plurality of second via layers penetrating at least one of the plurality of second insulating layers, respectively,
wherein at least one of the plurality of first insulating layers includes an organic material, and
wherein at least one of the plurality of second insulating layers includes an organic material.

13. The printed circuit board of claim 12, wherein density of at least one wiring of the plurality of second wiring layers is greater than density of at least one wiring of the plurality of first wiring layers.

14. The printed circuit board of claim 12, wherein at least one of the plurality of second wiring layers includes a fine circuit pattern having a line/space of 2 μm/2 μm or less.

15. The printed circuit board of claim 12, wherein the second substrate has a thickness less than a thickness of the first substrate.

16. The printed circuit board of claim 12, wherein an organic insulating material included in at least one of the plurality of second insulating layers is different from an organic insulating material included in at least one of the plurality of first insulating layers.

17. The printed circuit board of claim 12,
wherein, among the plurality of first via layers, a first via layer disposed on an uppermost side includes a first connection via connected to the metal layer,
wherein among the plurality of second via layers, a second via layer disposed on a lowermost side includes a second connection via connected to the metal layer, and
wherein the first and second connection vias are tapered in opposite directions.

18. The printed circuit board of claim 17,
wherein a width of an upper end of the first connection via is greater than a width of a lower end of the first connection via in a cross-section, and
wherein a width of the lower end of the second connection via is greater than a width of an upper end of the second connection via in the cross-section.

19. The printed circuit board of claim 12,
wherein the first substrate includes a core-type multilayer printed circuit board, and
wherein the second substrate includes a coreless-type multilayer printed circuit board.

20. The printed circuit board of claim 12, further comprising:
a first resist layer disposed on a lower side of the first substrate; and
a second resist layer disposed on an upper side of the second substrate,
wherein the first resist layer has a plurality of first openings each exposing at least a portion of the first wiring layer disposed on a lowermost side of the plurality of first wiring layers, and
wherein the second resist layer has a plurality of second openings each exposing at least a portion of the second wiring layer disposed on an uppermost side of the plurality of second wiring layers.

21. The printed circuit board of claim 20, further comprising:
a plurality of first connection metals disposed on the plurality of first openings, respectively, and each connected to at least a portion of the first wiring layer disposed on the lowermost side;
a plurality of second connection metals each disposed on at least a portion of the plurality of second openings and each connected to at least a portion of the second wiring layer disposed on the uppermost side; and
a semiconductor chip disposed on the second resist layer and connected to a second wiring layer disposed on the uppermost side through the plurality of second connection metals.

22. A printed circuit board, comprising:
a first substrate including a first wiring layer;
a second substrate disposed on the first substrate and including a second wiring layer;
a metal layer disposed between the first and second substrates; and
a bonding layer disposed between the first and second substrates,
wherein a wiring line having a minimum line width among wiring lines of the second wiring layer has a line width smaller than a line width of a wiring line having a minimum line width among wiring lines of the first wiring layer.

23. The printed circuit board of claim 22, wherein a minimum distance among distances between wiring lines of the second wiring layer is smaller than a minimum distance among distances between wiring lines of the first wiring layer.

24. The printed circuit board of claim 22, wherein a minimum pitch among pitches of wiring pads of the second wiring layer is smaller than a minimum pitch among pitches of wiring pads of the first wiring layer.

25. The printed circuit board of claim 22, further comprising:
a heterogeneous metal layer disposed in the metal layer;
wherein the heterogeneous metal layer includes a metal different from the metal layer.

26. The printed circuit board of claim 22,
wherein the bonding layer is disposed adjacent to the metal layer, and
wherein a thickness of the bonding layer is substantially the same as a thickness of the metal layer.

27. The printed circuit board of claim 22,
wherein each of the first and second substrates includes an organic material, and
wherein the bonding layer includes an inorganic material.

28. The printed circuit board of claim 22, wherein the metal layer includes nano-twinned copper.

29. A method of manufacturing a printed circuit board, the method comprising:
preparing a first substrate including a plurality of first wiring layers and having a first metal layer formed on an outermost side;
forming a first inorganic insulating film covering at least a portion of the first metal layer on the outermost side of the first substrate;
preparing a second substrate including a plurality of second wiring layers and having a second metal layer formed on an outermost side;
forming a second inorganic insulating film covering at least a portion of the second metal layer on the outermost side of the second substrate; and
bonding the first and second substrates to each other such that the first and second inorganic insulating films are bonded to each other and the first and second metal layers are bonded to each other,
wherein each of the first and second substrates includes an organic material.

30. The method of claim 29, wherein, in the preparing the second substrate, at least one of the plurality of second wiring layers has wiring density greater than that of at least one of the plurality of first wiring layers.

31. The method of claim 29, wherein, in the preparing the second substrate, at least one of the plurality of second wiring layers is formed to include a fine circuit pattern having a line/space of 2 μm/2 μm or less.

32. The method of claim 29, further comprising:
exposing a surface of the first metal layer by flattening the first metal layer and the first inorganic insulating film after the forming the first inorganic insulating film; and
exposing a surface of the second metal layer by flattening the second metal layer and the second inorganic insulating film after the forming the second inorganic insulating film.

33. The method of claim 32, wherein the bonding the first and second substrate to each other includes:
causing the first and second inorganic insulating film to be in contact with each other and causing the first and second metal layer to be in contact with each other,
bonding the first and second inorganic insulating films to each other at a first temperature, and
bonding the first and second metal layers to each other at a second temperature,
wherein the second temperature is higher than the first temperature.

34. The method of claim 33, wherein the bonding the first and second substrate to each other includes:
applying a metal paste including a metal different from the first and second metal layers between the first and second metal layers,
causing the first and second inorganic insulating film to be in contact with each other and causing the first and second metal layer to be in contact with the metal paste,
bonding the first and second inorganic insulating films to each other at a first temperature, and
bonding the first and second metal layers to each other through the metal paste at a second temperature,
wherein the second temperature is higher than the first temperature.

35. The method of claim 29,
wherein in the preparing the first substrate and the preparing the second substrate, the first substrate includes a plurality of first insulating layers, a plurality of first wiring layers disposed on or in the plurality of first insulating layers, respectively, and a plurality of first via layers penetrating at least one of the plurality of first insulating layers, respectively, and the second substrate includes a plurality of second insulating layers, a plurality of second wiring layers disposed on or in the plurality of second insulating layers, respectively, and a plurality of second via layers penetrating at least one of the plurality of second insulating layers, respectively,
wherein at least one of the plurality of first insulating layers includes an organic material,
wherein at least one of the plurality of second insulating layers includes an organic material,
wherein, among the plurality of first wiring layers, the first wiring layer disposed on an uppermost side includes the first metal layer, and
wherein, among the plurality of second wiring layers, the second wiring layer disposed on a lowermost side includes the second metal layer.

36. A printed circuit board, comprising:
a first substrate including a plurality of first insulating layers, a plurality of first wiring layers disposed on or in the plurality of first insulating layers, and a plurality of first via layers penetrating at least one of the plurality of first insulating layers, respectively;
a second substrate disposed on the first substrate and including a plurality of second insulating layers, a plurality of second wiring layers disposed on or in the plurality of second insulating layers, respectively, and a plurality of second via layers penetrating at least one of the plurality of second insulating layers, respectively;
a metal layer disposed between the first and second substrates to connect a via layer among the plurality of first via layers which is closest to the second substrate and a via layer among the plurality of second via layers which is closed to the first substrate to each other; and
an insulating bonding layer disposed between the first and second substrates to connect to the first and second substrates to each other,
wherein the via layer among the plurality of first via layers which is closest to the second substrate and the plurality of second via layers are tapered in opposite directions.

37. The printed circuit board of claim 36, wherein the metal layer includes a first metal layer disposed on an uppermost side of the first substrate and a second metal layer disposed on a lowermost side of the second substrate.

38. The printed circuit board of claim 37, wherein the first and second metal layers are bonded to each other such that side surfaces thereof are disposed to be shifted from each other.

39. The printed circuit board of claim 37, wherein the first metal layer and the second metal layer are directly bonded to each other.

40. The printed circuit board of claim 37, wherein the metal layer further includes a third metal layer disposed between the first and second metal layers and including a metal different from that of the first and second metal layers.

41. The printed circuit board of claim 37,
wherein the first metal layer has a thickness less than each of the plurality of first wiring layers, and
wherein the second metal layer has a thickness less than each of the plurality of second wiring layers.

42. The printed circuit board of claim 36, wherein the insulating bonding layer includes a material different from the plurality of first insulating layers and the second insulating layers.

43. The printed circuit board of claim 36, wherein density of at least one wiring of the plurality of second wiring layers is greater than density of at least one wiring of the plurality of first wiring layers.

44. A printed circuit board, comprising:
a first substrate including a plurality of first insulating layers, a plurality of first wiring layers disposed on or in the plurality of first insulating layers, and a plurality of first via layers penetrating at least one of the plurality of first insulating layers, respectively;
a second substrate disposed on the first substrate and including a plurality of second insulating layers, a plurality of second wiring layers disposed on or in the plurality of second insulating layers, respectively, and a plurality of second via layers penetrating at least one of the plurality of second insulating layers, respectively;
a metal layer disposed between the first and second substrates to connect a via layer among the plurality of first via layers which is closest to the second substrate and a via layer among the plurality of second via layers which is closed to the first substrate to each other; and
an insulating bonding layer disposed between the first and second substrates to connect to the first and second substrates to each other,
wherein an outermost via layer of the plurality of second via layers, connected to an outermost wiring layer of the plurality of second wiring layers, has a tapered shape such that a width thereof increases in a direction towards the metal layer.

45. The printed circuit board of claim 44, wherein the metal layer includes a first metal layer disposed on an uppermost side of the first substrate and a second metal layer disposed on a lowermost side of the second substrate.

46. The printed circuit board of claim 45, wherein the first metal layer and the second metal layer are directly bonded to each other.

47. The printed circuit board of claim 45, wherein the metal layer further includes a third metal layer disposed between the first and second metal layers and including a metal different from that of the first and second metal layers.

48. The printed circuit board of claim 44, wherein density of at least one wiring of the plurality of second wiring layers is greater than density of at least one wiring of the plurality of first wiring layers.

49. The printed circuit board of claim 44, wherein an outermost via layer of the plurality of first via layers, connected to an outermost wiring layer of the plurality of first wiring layers, has a tapered shape such that a width thereof increases in a direction towards the metal layer.
